(19) United States
(12) Patent Application Publication
(10) Pub. No.: US 2025/0328177 A1
(43) Pub. Date: Oct. 23, 2025

(54) TWO-STAGE PROCESSOR VOLTAGE REGULATION

(71) Applicant: INTERNATIONAL BUSINESS MACHINES CORPORATION, ARMONK, NY (US)

(72) Inventors: MICHAEL SPERLING, POUGHKEEPSIE, NY (US); WILLIAM V. HUOTT, HOLMES, NY (US); DANIEL MARK DREPS, GEORGETOWN, TX (US); JUSTIN HENSPETER, GEORGETOWN, TX (US); SUNGJUN CHUN, POUGHKEEPSIE, NY (US); LUKE L. JENKINS, POUGHKEEPSIE, NY (US)

(21) Appl. No.: 18/643,616

(22) Filed: Apr. 23, 2024

(51) Int. Cl. G06F 1/26; H01L 25/10; H02M 3/00

(52) U.S. Cl. CPC G06F 1/26; H01L 25/105; H02M 3/003

(57) ABSTRACT

Two-stage processor voltage regulation according to an example includes receiving, by a buck switching regulator circuit formed in an active interposer that is positioned on a module, a voltage. The buck switching regulator circuit outputs to each of one or more chip dies positioned on the active interposer based on the received voltage, a first regulated voltage. Each of one or more on-chip voltage regulators in each of the one or more chip dies generates based on the first regulated voltage, a respective second regulated voltage.

### BACKGROUND

The present disclosure relates to methods, apparatus, and products for two-stage processor voltage regulation.

### SUMMARY

According to embodiments of the present disclosure, various methods, apparatus and products for two-stage processor voltage regulation are described herein. In some aspects, two-stage processor voltage regulation includes receiving, by a buck switching regulator circuit formed in an active interposer that is positioned on a module, a voltage. The buck switching regulator circuit outputs to each of one or more chip dies positioned on the active interposer based on the received voltage, a first regulated voltage. Each of one or more on-chip voltage regulators in each of the one or more chip dies generates based on the first regulated voltage, a respective second regulated voltage.

### BRIEF DESCRIPTION OF THE DRAWINGS

FIG. 1 sets forth an example computing environment according to aspects of the present disclosure.

FIG. 2 sets forth an example system with two-stage processor voltage regulation according to aspects of the present disclosure.

FIG. 3 sets forth a flowchart of an example method for two-stage processor voltage regulation according to aspects of the present disclosure.

### DETAILED DESCRIPTION

In general, a voltage regulator is a circuit that is designed to maintain a constant output voltage level as operating conditions change over time. That is, the voltage regulator may be an electronic device or system designed to receive an input voltage and automatically maintain a constant voltage level on one or more output terminals. Depending on the design, a voltage regulator can be used to regulate one or more alternating current (AC) or direct current (DC) voltages. Voltage regulators can be included in electronic devices such as, for example, computer power supplies where they can be used to stabilize DC voltages used to supply power to electronic components such as processor(s), memory devices, and other types of integrated circuits (ICs).

There are several types of voltage regulators such as, for example, switching regulators, linear regulators, and cascaded regulators that may include both switching and linear regulators in a cascaded architecture. One particular type of linear regulator is a low dropout (LDO) regulator. An LDO regulator is a DC linear voltage regulator that may regulate the output voltage even when the supply voltage is close to the output voltage. That is, the LDO regulator may maintain voltage regulation with small differences between supply voltage and load voltage. Another type of voltage regulator is a buck switching regulator (e.g., a step-down regulator circuit). The buck switching regulator is a type of switch mode power supply circuit designed to efficiently reduce DC voltage from a higher voltage to a lower voltage.

In some applications, it may be difficult or impossible to power all power domains from external/off-processor regulators, so regulation close to the chip may be used. On-chip voltage regulation may be accomplished with linear regulators, which may be inefficient and limited to low currents, compared to switching regulators. New package advances allow switching regulation to be placed closer to the chip, such as by putting passive elements like capacitors and inductors on a module or interposer.

Some examples disclosed herein are directed to distributed two-stage processor voltage regulation with an active interposer. Some examples include a buck switching regulator packaged on an active interposer, providing a first stage of regulation or pre-regulation to a plurality of processor cores and/or chips. The buck switching regulator may receive a high voltage at a low current, and bring the voltage down to an appropriate chip die voltage level. The pre-regulated voltage is then distributed by the buck switching regulator across the second stage (e.g., across a module including a plurality of processor chip dies). In some examples, the pre-regulated output from the buck switching regulator is precisely and independently regulated on each individual processor chip die with one or more second stage on-chip regulators (e.g., linear or buck regulators). In some examples, a single buck switching regulator in the active interposer feeds multiple second-stage regulators (e.g., on-chip regulators). Multiple buck switching regulators on an active interposer may be used to meet current demands.

Some examples of the present disclosure are directed to an apparatus for two stage processor voltage regulation, which includes a board, a module fixed upon the board, and an active interposer fixed upon the module. The apparatus further includes a buck switching regulator circuit packaged on the active interposer, wherein the buck switching regulator circuit provides pre-regulation to downstream processor cores/chips. The apparatus further includes a chip die fixed upon the active interposer, and a second stage regulator fixed on the chip die for precise voltage regulation, wherein the second stage regulator is a linear or buck regulator.

Some examples of the present disclosure are directed to a computer-implemented method for two stage processor core/chip voltage regulation. The computer-implemented method includes pre-regulating voltage utilizing a buck switching regulator circuit fixed on an active interposer. The method further includes finely regulating, the pre-regulated voltage of a processor domain utilizing a second stage regulator, fixed on the processor core, wherein the second stage regulator is a linear or buck regulator.

Some examples of the present disclosure result in less leakage power burned in the processor because tighter regulation closer to the chip results in lower core voltages (i.e., less voltage overhead compared to external regulation). Some examples result in lower I2R/conduction power loss because regulation closer to the processor means higher voltage and lower current may be bussed to the module or active interposer. Some examples provide finer control (e.g., finer resolution) of the processor voltage and better power efficiency compared to performing all of the regulation on a separate die. Some examples provide cost savings and space savings because fewer external regulators may be used in the system. This space may be used to add more processing and memory capacity. Some examples provide sustainability and carbon footprint improvements because fewer external regulators may be used (i.e., removes the carbon footprint attached to every external regulator from a product). The on-processor regulation reduces the number of redundancy phases used in the system, which has size, cost, and carbon footprint implications.

An example of the present disclosure is directed to a method for two-stage processor voltage regulation. The method includes receiving, by a buck switching regulator circuit formed in an active interposer that is positioned on a module, a voltage. The method includes outputting, from the buck switching regulator circuit to each of one or more chip dies positioned on the active interposer based on the received voltage, a first regulated voltage. The method includes generating, by each of one or more on-chip voltage regulators in each of the one or more chip dies based on the first regulated voltage, a respective second regulated voltage.

Examples of the method include various technical features that yield technical effects that provide various improvements to computer technology. For instance, some examples include the technical features of a buck switching regulator circuit formed in an active interposer that is positioned on a module, and outputting, from the buck switching regulator circuit to each of one or more chip dies positioned on the active interposer based on the received voltage, a first regulated voltage. Some examples further include the technical features of generating, by each of one or more on-chip voltage regulators in each of the one or more chip dies based on the first regulated voltage, a respective second regulated voltage. These technical features yield the technical effect of less leakage power being burned in the processor because tighter regulation closer to the chip by the buck switching regulator circuit results in lower core voltages (i.e., less voltage overhead compared to external regulation). Some examples result in lower I2R/conduction power loss because regulation closer to the processor means higher voltage and lower current may be bussed to the processor. Some examples provide cost savings and space savings because fewer external regulators may be used in the system.

In some examples of the method, the one or more chip dies includes a plurality of chip dies that each receive the first regulated voltage from the buck switching regulator circuit. In some examples, each chip die in the plurality of chip dies includes a plurality of on-chip voltage regulators that each receive the first regulated voltage from the buck switching regulator circuit. In some examples, each chip die is a processor chip die that includes one or more processor cores.

In some examples of the method, the module is formed on a board. In some examples, the voltage received by the buck switching regulator circuit is received from a board voltage regulator positioned on the board that provides the voltage through the board, the module, and the active interposer.

In some examples of the method, each of the one or more on-chip voltage regulators is a buck switching regulator circuit. In some examples, each of the one or more on-chip voltage regulators is a linear regulator circuit.

Another example of the present disclosure is directed to a system for two-stage processor voltage regulation. The system includes a module, an active interposer positioned on the module, and one or more chip dies positioned on the active interposer. The system includes a buck switching regulator circuit formed in the active interposer to receive a voltage, and output, to each of the one or more chip dies based on the received voltage, a first regulated voltage. The system includes one or more on-chip voltage regulators in each of the one or more chip dies to generate, based on the first regulated voltage, a respective second regulated voltage.

Examples of the system include various technical features that yield technical effects that provide various improvements to computer technology. For instance, some examples include the technical features of a buck switching regulator circuit formed in an active interposer that is positioned on a module, and outputting, from the buck switching regulator circuit to each of one or more chip dies positioned on the active interposer based on the received voltage, a first regulated voltage. Some examples further include the technical features of generating, by each of one or more on-chip voltage regulators in each of the one or more chip dies based on the first regulated voltage, a respective second regulated voltage. These technical features yield the technical effect of less leakage power being burned in the processor because tighter regulation closer to the chip by the buck switching regulator circuit results in lower core voltages (i.e., less voltage overhead compared to external regulation). Some examples result in lower I2R/conduction power loss because regulation closer to the processor means higher voltage and lower current may be bussed to the processor. Some examples provide cost savings and space savings because fewer external regulators may be used in the system.

In some examples of the system, the one or more chip dies includes a plurality of chip dies that each receive the first regulated voltage from the buck switching regulator circuit. In some examples, each chip die in the plurality of chip dies includes a plurality of on-chip voltage regulators that each receive the first regulated voltage from the buck switching regulator circuit. In some examples, each chip die is a processor chip die that includes one or more processor cores.

In some examples of the system, the module is formed on a board. In some examples, the voltage received by the buck switching regulator circuit is received from a board voltage regulator positioned on the board that provides the voltage through the board, the module, and the active interposer.

In some examples of the system, each of the one or more on-chip voltage regulators is a buck switching regulator circuit. In some examples, each of the one or more on-chip voltage regulators is a linear regulator circuit.

Another example of the present disclosure is directed to a computer program product comprising a computer readable storage medium. The computer readable storage medium comprises computer program instructions that, when executed: control a buck switching regulator circuit formed in an active interposer that is positioned on a module to receive a voltage, and output, to each of one or more chip dies positioned on the active interposer based on the received voltage, a first regulated voltage; and control one or more on-chip voltage regulators in each of the one or more chip dies to generate, based on the first regulated voltage, a respective second regulated voltage.

Examples of the computer program produce include various technical features that yield technical effects that provide various improvements to computer technology. For instance, some examples include the technical features of controlling a buck switching regulator circuit formed in an active interposer that is positioned on a module to receive a voltage, and output, to each of one or more chip dies positioned on the active interposer based on the received voltage, a first regulated voltage; and controlling one or more on-chip voltage regulators in each of the one or more chip dies to generate, based on the first regulated voltage, a respective second regulated voltage. These technical features yield the technical effect of less leakage power being burned in the processor because tighter regulation closer to the chip by the buck switching regulator circuit results in lower core voltages (i.e., less voltage overhead compared to external regulation). Some examples result in lower I2R/conduction power loss because regulation closer to the processor means higher voltage and lower current may be bussed to the processor. Some examples provide cost savings and space savings because fewer external regulators may be used in the system.

In some examples of the computer program product, the one or more chip dies includes a plurality of chip dies that each receive the first regulated voltage from the buck switching regulator circuit. In some examples, each chip die in the plurality of chip dies includes a plurality of on-chip voltage regulators that each receive the first regulated voltage from the buck switching regulator circuit. In some examples, each chip die is a processor chip die that includes one or more processor cores.

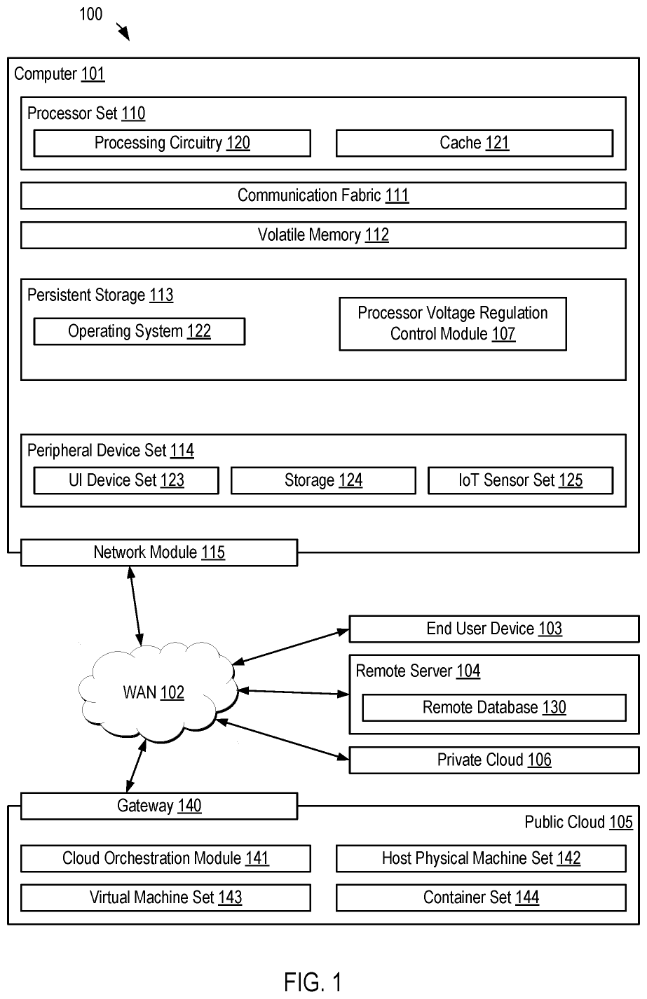

FIG. 1 sets forth an example computing environment according to aspects of the present disclosure. Computing environment 100 contains an example of an environment for the execution of at least some of the computer code involved in performing the various methods described herein, such as processor voltage regulation control module 107. Functionality of process voltage regulation control module 107 may be implemented in hardware, software, or a combination of hardware and software, and may be distributed throughout various blocks of computing environment 100. In addition to processor voltage regulation control module 107, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and processor voltage regulation control module 107, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

Processor set 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document. These computer readable program instructions are stored in various types of computer readable storage media, such as cache 121 and the other storage media discussed below. The program instructions, and associated data, are accessed by processor set 110 to control and direct performance of the computer-implemented methods. In computing environment 100, at least some of the instructions for performing the computer-implemented methods may be stored in processor voltage regulation control module 107 in persistent storage 113.

Communication fabric 111 is the signal conduction path that allows the various components of computer 101 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in processor voltage regulation control module 107 typically includes at least some of the computer code involved in performing the computer-implemented methods described herein.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database), this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the computer-implemented methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

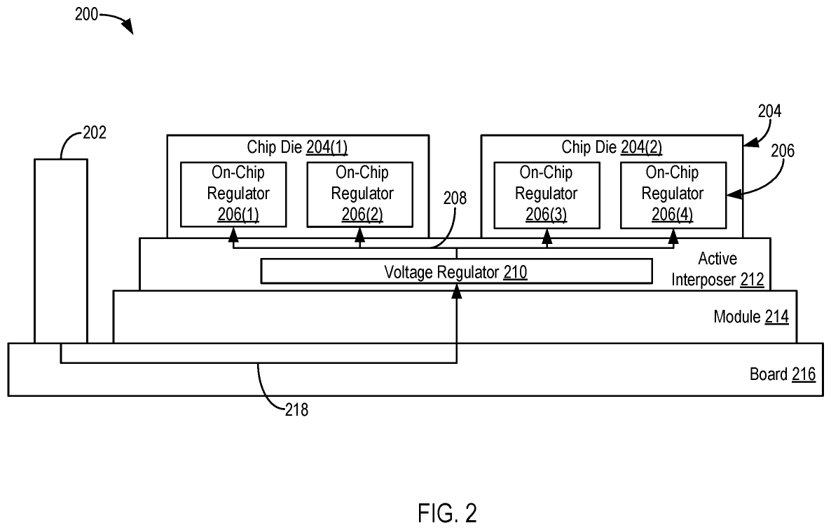

FIG. 2 sets forth an example system 200 with two-stage processor voltage regulation according to aspects of the present disclosure. System 200 is an example implementation of elements of computing environment 100 (FIG. 1), and may implement some or all of the functionality of processor voltage regulation control module 107. System 200 includes board voltage regulator 202, chip dies 204(1)-204(2) (collectively referred to as chip dies 204), active interposer 212, module 214, and board 216 (e.g., printed circuit board). Active interposer 212 includes a voltage regulator 210 formed therein. In an example, voltage regulator 210 is a buck switching regulator circuit.

Chip die 204(1) includes on-chip voltage regulators 206(1) and 206(2). Chip die 204(2) includes on-chip voltage regulators 206(3) and 206(4). On-chip voltage regulators 206(1)-206(4) are collectively referred to as on-chip voltage regulators 206. In some examples, on-chip voltage regulators 206(1) and 206(2) are used for different power domains of chip die 204(1), and on-chip voltage regulators 206(3) and 206(4) are used for different power domains of chip die 204(2). In some examples, chip dies 204 are processor chip dies that each include a processor core or a plurality of processor cores. In some examples, each of the on-chip voltage regulators 206 is a buck switching regulator circuit. In other examples, each of the on-chip voltage regulators 206 is a linear regulator circuit (e.g., LDO regulator).

Board voltage regulator 202 and module 214 are formed on a top surface of board 216. Active interposer 212 is formed on a top surface of module 214. Chip dies 204 are formed on a top surface of active interposer 212. Although two chip dies 204 are shown in the illustrated example, other examples may include more or less than two chip dies 204. Although two on-chip voltage regulators 206 are shown for each of the chip dies 204, other examples may include more or less than two on-chip voltage regulators 206 in each of the chip dies 204.

Board voltage regulator 202 outputs a voltage to voltage regulator 210 via conductive link 218, which extends through at least a portion of board 216, module 214, and active interposer 212 to reach voltage regulator 210. Voltage regulator 210 generates a first regulated voltage based on the received voltage from board voltage regulator 202. Voltage regulator 210 outputs the first regulated voltage via conductive links 208, which are coupled to on-chip regulators 206. Each of the on-chip regulators 206 generates a respective second regulated voltage based on the received first regulated voltage. The on-chip regulators 206 may each output the second regulated voltage to one or more elements (e.g., processor cores) within the chip die 204 containing the on-chip regulator 206.

In some examples, system 200 provides distributed two-stage processor voltage regulation with an active interposer 212. In some examples, a buck switching regulator circuit (e.g., voltage regulator 210) packaged on active interposer 212 provides pre-regulation to a plurality of processor cores and/or chips (e.g., chip dies 204 or processor cores within chip dies 204). In some examples, the pre-regulated output from the buck switching regulator circuit is then more precisely regulated on each chip die 204 with one or more second stage regulators (e.g., on-chip voltage regulators 206). In some examples, a single buck switching regulator (e.g., voltage regulator 210) in the active interposer 212 feeds multiple second-stage regulators (e.g., on-chip voltage regulators 206), which may be distributed across multiple chip dies 204.

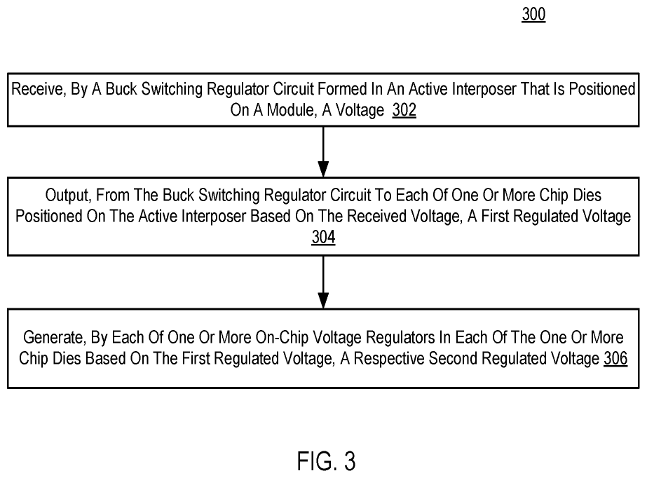

FIG. 3 sets forth a flowchart of an example method 300 for two-stage processor voltage regulation according to aspects of the present disclosure. In a particular embodiment, the method 300 is performed utilizing system 200 (FIG. 2). The method 300 includes receiving 302, by a buck switching regulator circuit formed in an active interposer that is positioned on a module, a voltage. The method 300 further includes outputting 304, from the buck switching regulator circuit to each of one or more chip dies positioned on the active interposer based on the received voltage, a first regulated voltage. The method 300 further includes generating 306, by each of one or more on-chip voltage regulators in each of the one or more chip dies based on the first regulated voltage, a respective second regulated voltage.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method for two-stage processor voltage regulation, comprising:
receiving, by a buck switching regulator circuit formed in an active interposer that is positioned on a module, a voltage;
outputting, from the buck switching regulator circuit to each of one or more chip dies positioned on the active interposer based on the received voltage, a first regulated voltage; and
generating, by each of one or more on-chip voltage regulators in each of the one or more chip dies based on the first regulated voltage, a respective second regulated voltage.

2. The method of claim 1, wherein the one or more chip dies includes a plurality of chip dies that each receive the first regulated voltage from the buck switching regulator circuit.

3. The method of claim 2, wherein each chip die in the plurality of chip dies includes a plurality of on-chip voltage regulators that each receive the first regulated voltage from the buck switching regulator circuit.

4. The method of claim 1, wherein each chip die is a processor chip die that includes one or more processor cores.

5. The method of claim 1, wherein the module is formed on a board.

6. The method of claim 5, wherein the voltage received by the buck switching regulator circuit is received from a board voltage regulator positioned on the board that provides the voltage through the board, the module, and the active interposer.

7. The method of claim 1, wherein each of the one or more on-chip voltage regulators is a buck switching regulator circuit.

8. The method of claim 1, wherein each of the one or more on-chip voltage regulators is a linear regulator circuit.

9. A system for two-stage processor voltage regulation, comprising:
a module;
an active interposer positioned on the module;
one or more chip dies positioned on the active interposer;
a buck switching regulator circuit formed in the active interposer to receive a voltage, and output, to each of the one or more chip dies based on the received voltage, a first regulated voltage; and
one or more on-chip voltage regulators in each of the one or more chip dies to generate, based on the first regulated voltage, a respective second regulated voltage.

10. The system of claim 9, wherein the one or more chip dies includes a plurality of chip dies that each receive the first regulated voltage from the buck switching regulator circuit.

11. The system of claim 10, wherein each chip die in the plurality of chip dies includes a plurality of on-chip voltage regulators that each receive the first regulated voltage from the buck switching regulator circuit.

12. The system of claim 9, wherein each chip die is a processor chip die that includes one or more processor cores.

13. The system of claim 9, wherein the module is formed on a board.

14. The system of claim 13, wherein the voltage received by the buck switching regulator circuit is received from a board voltage regulator positioned on the board that provides the voltage through the board, the module, and the active interposer.

15. The system of claim 9, wherein each of the one or more on-chip voltage regulators is a buck switching regulator circuit.

16. The system of claim 9, wherein each of the one or more on-chip voltage regulators is a linear regulator circuit.

17. A computer program product comprising a computer readable storage medium, wherein the computer readable storage medium comprises computer program instructions that, when executed:
control a buck switching regulator circuit formed in an active interposer that is positioned on a module to receive a voltage, and output, to each of one or more chip dies positioned on the active interposer based on the received voltage, a first regulated voltage; and
control one or more on-chip voltage regulators in each of the one or more chip dies to generate, based on the first regulated voltage, a respective second regulated voltage.

18. The computer program product of claim 17, wherein the one or more chip dies includes a plurality of chip dies that each receive the first regulated voltage from the buck switching regulator circuit.

19. The computer program product of claim 18, wherein each chip die in the plurality of chip dies includes a plurality of on-chip voltage regulators that each receive the first regulated voltage from the buck switching regulator circuit.

20. The computer program product of claim 17, wherein each chip die is a processor chip die that includes one or more processor cores.
